(19) United States
(12) Patent Application Publication
(10) Pub. No.: US 2026/0256010 A1
(43) Pub. Date: Aug. 27, 2026

(54) HIGH-POWER TVS PACKAGING STRUCTURE AND PACKAGING METHOD THEREOF

(71) Applicant: HEFEI SMAT TECHNOLOGY CO. LTD., HEFEI CITY (CN)

(72) Inventor: Xiaochun TAN, HEFEI CITY (CN)

(21) Appl. No.: 19/460,476

(22) Filed: Jan. 27, 2026

(30) Foreign Application Priority Data
Feb. 27, 2025 (CN) 202510225271.5

(51) Int. Cl. H10W 72/00; H10W 74/01; H10W 95/00

(52) U.S. Cl. CPC H10W 72/823; H10W 72/01; H10W 74/012; H10W 95/00

(57) ABSTRACT

A high-power TVS packaging structure and a packaging method thereof are provided. The method comprises: mounting a chip on a substrate, encapsulating the chip and exposing a front output end of the chip; exposing a pin of the substrate, and electroplating a post within a drilled hole; electroplating a routing layer electrically connecting the front output end with the post, the routing layer, the front output end, and the post being electroplated as a whole, the routing layer comprising a narrow segment; completely encapsulating the routing layer, wherein if an input power of a circuit is greater than a rated power of the chip, the narrow segment breaks. When an abnormal overvoltage exceeding a breakdown voltage of the package occurs in the circuit, heat accumulates at the narrow segment, which is fused into an open circuit, thereby avoiding the package being burned and causing a fire.

### CROSS-REFERENCE TO RELATED APPLICATIONS

This present disclosure claims priority to a Chinese patent application No. 202510225271.5, filed on Feb. 27, 2025, and entitled “high-power TVS packaging structure and packaging method thereof”, the entire contents of which are incorporated herein by reference, including the specification, claims, drawings and abstract.

### FIELD OF TECHNOLOGY

The present disclosure relates to a field of chip packaging, particularly, to a high-power TVS (Transient Voltage Suppressor) packaging structure and a packaging method thereof.

### BACKGROUND

TVS (Transient Voltage Suppressor) is a semiconductor device used to quickly suppress transient overvoltage and protect electronic equipment from voltage transients and surges. It is also called a transient voltage suppression diode and is a new product developed based on voltage regulator tube technology. When the two ends of the TVS tube are subjected to an instantaneous high-energy impact, it can rapidly reduce its impedance to an extremely low level, absorb a large current at the same time, and clamp the voltage between its two ends to a predetermined value, thereby ensuring that the subsequent circuit components are not damaged by the transient high-energy impact. According to the power level, TVS chips can be divided into high-power TVS and low-power TVS. Generally speaking, a peak pulse power ≥3000 W is defined as high-power TVS.

TVS usually adopts a diode-type axial lead packaging structure. The core unit of TVS is a chip, which is mainly made of semiconductor silicon wafers or selenium wafers. During packaging, the electrodes of the chip are electrically led out, and then the chip and the electrically leading lines are encapsulated using an encapsulation material process. The encapsulation shell plays the role of placing, fixing, sealing, protecting the chip and enhancing the electrothermal performance. The interface for electrical installation left outside the encapsulation shell is a pin, which establishes an electrical connection with other devices through wires on the printed board and serves as a bridge between the internal world of the chip and the external circuit of the encapsulation shell.

After the high-power TVS chip is packaged, it is connected in parallel with the protected device. When the circuit works normally, the TVS chip is in a cut-off state and does not affect the circuit operation. When an abnormal overvoltage occurs in the circuit and reaches a breakdown voltage of the TVS chip, the chip directly fails, and the TVS diode changes from a high-resistance state to a low-resistance state, becoming a conducting circuit. In this case, the TVS tube will release high energy, damage the protected electronic components, and even cause a fire.

### SUMMARY OF THE DISCLOSURE

To solve the above problems in the prior art, the present disclosure provides a high-power TVS packaging structure and a packaging method thereof.

To achieve the above object, a high-power TVS packaging method proposed by the present disclosure comprises the following steps:
chip packaging: mounting a chip on a substrate with an electroplated pin, encapsulating the chip and grinding a top of an encapsulation surface until a front output end of the chip is exposed;
drilling and electroplating: drilling vertically through the top of the encapsulation surface until the pin is exposed, and electroplating a post within a drilled hole;
routing layer electroplating: electroplating a routing layer on the top of the encapsulation surface, the routing layer electrically connecting the front output end of the chip with the post, the routing layer, the front output end of the chip, and the post being electroplated as a whole, the routing layer comprising a narrow segment; continue encapsulating to completely encapsulate the routing layer, wherein if an input power of a circuit is greater than a rated power of the chip, the narrow segment breaks;
product unitization: stripping the substrate to obtain a package product unit.

Further, in the step of chip packaging, the substrate is provided, the substrate being electroplated with a solder pad and the pin; after encapsulation and grinding, top surfaces of the solder pad and pin are exposed; a back surface of the chip is mounted on the solder pad and encapsulated, so that the chip, the solder pad, and the pin are all completely encapsulated.

Further, in the step of routing layer electroplating, a film block is mounted on a corresponding position of the top of the encapsulation surface exposing the front output end of the chip before the routing layer is electroplated, then the routing layer is electroplated; through the film block, the narrow segment of the routing layer is formed at a position where the film block is mounted.

Further, in the step of routing layer electroplating, the film block is a photoresist film.

Further, in the step of routing layer electroplating, a part of the routing layer closing to the post is thinned by etching to form the narrow segment of the routing layer.

Further, in the step of routing layer electroplating, the routing layer extends horizontally along the top of the encapsulation surface exposing the front output end of the chip, and the front end of the chip is electrically connected to the pin through the routing layer and the post.

Further, in the step of product unitization, after stripping the substrate, the solder pad and the pin are flush with a bottom surface of the package and exposed.

A high-power TVS packaging structure is provided and comprises a package, wherein the package encapsulates:
a solder pad and a pin, the solder pad being set on one side of the pin;
a chip, a back surface of the chip being mounted towards the solder pad, and a front surface of the chip having an output end;
a post vertically electroplated on the pin; and
a routing layer, the routing layer electrically connecting the front output end of the chip with the post, the routing layer, the front output end of the chip, and the post being electroplated as a whole, the routing layer comprising a narrow segment, wherein if an input power of a circuit is greater than a rated power of the chip, the narrow segment breaks.

Further, the solder pad and the pin are formed by electroplating on a substrate at the same time; after encapsulation and grinding, top surfaces of the solder pad and the pin are exposed; the back surface of the chip is mounted on the solder pad and encapsulated; the front output end of the chip is exposed by grinding, and the top surface of the pin is exposed by drilling on an encapsulation surface; the post is formed by electroplating within a hole.

Further, the routing layer extends horizontally along a top of the encapsulation surface exposing the front output end of the chip, the front end of the chip is electrical connected to the pin through the routing layer and the post, the routing layer is encapsulated, and an overall encapsulation forms the package.

Further, a film block is mounted on a corresponding position of the top of the encapsulation surface exposing the front output end of the chip before the routing layer is electroplated, then the routing layer is electroplated; through the film block, the narrow segment of the routing layer is formed at a position where the film block is mounted.

Further, the film block is a photoresist film.

Further, a part of the routing layer closing to the post is thinned by etching to form the narrow segment of the routing layer.

Further, after stripping the package from the substrate, the solder pad and the pin are flush with a bottom surface of the package and exposed.

In the present disclosure, by locally thinning the electroplated routing layer into a narrow segment of a certain size, when the package is connected in parallel to the circuit of the protected device, if an abnormal overvoltage exceeding the breakdown voltage of the package occurs in the circuit, heat accumulates at the narrow segment of the package and is fused into an open circuit, avoiding the situation where the package is burned and causing a fire.

### BRIEF DESCRIPTION OF THE DRAWINGS

FIGS. 1-6 are cross-sectional views of the chip packaging step of a high-power TVS packaging method of the present disclosure;

FIGS. 7-8 are cross-sectional views of the drilling and electroplating step of a high-power TVS packaging method of the present disclosure;

FIGS. 9-13 are cross-sectional views of a first embodiment of the routing layer electroplating step of a high-power TVS packaging method of the present disclosure;

FIGS. 14-17 are cross-sectional views of a second embodiment of the routing layer electroplating step of a high-power TVS packaging method of the present disclosure;

FIG. 18 is a product cross-sectional view of the first embodiment of the high-power TVS packaging structure of the present disclosure;

FIG. 19 is a product cross-sectional view of the second embodiment of the high-power TVS packaging structure of the present disclosure.

In the drawings: 1. Package; 2. Chip; 3. Post; 4. Routing layer; 5. Solder pad; 6. Pin; 7. Narrow segment.

### DETAILED DESCRIPTION OF THE DISCLOSURE

The content of the present disclosure will be described below in conjunction with specific embodiments. Examples of the embodiments are shown in the accompanying drawings, wherein the same or similar reference numerals denote the same or similar components or components with the same or similar functions throughout.

The directional terms mentioned in the present disclosure, such as: up, down, left, right, front, back, inside, outside, front, back, side, etc., are only for referring to the directions of the accompanying drawings. The embodiments described below with reference to the accompanying drawings and the directional terms used are exemplary and only for explaining the present disclosure, and should not be construed as limiting the present disclosure. In addition, the various specific processes and materials provided by the present disclosure are examples that those of ordinary skill in the art can realize the application of other processes and/or the use of other materials.

To better understand the purpose, structure and function of the present disclosure, a high-power TVS packaging method proposed by the present disclosure will be described in further detail below with reference to the accompanying drawings. The process comprises the following steps:
Chip 2 packaging: Mount a chip 2 on a substrate with a electroplated pin 6, encapsulate the chip 2, and grind a top of an encapsulation surface until the front output end of the chip 2 is exposed;
Drilling and electroplating: Drill vertically on the top of the encapsulation surface until the pin 6 is exposed, and electroplate a post 3 in the drilled hole;
Routing layer 4 electroplating: Electroplate a routing layer 4 on the top of the encapsulation surface, where the routing layer 4 electrically connects the output end of the chip 3 with the post 3, and the routing layer 4, the front output end of the chip 2, and the post 3 are electroplated as a whole. The routing layer 4 comprises a narrow segment 7, and encapsulation is continued to completely encapsulate the routing layer 4. When the input power of the circuit is greater than the rated power of the chip 2, the narrow segment 7 breaks;
Product unitization: Strip the substrate to obtain a package 1 product unit.

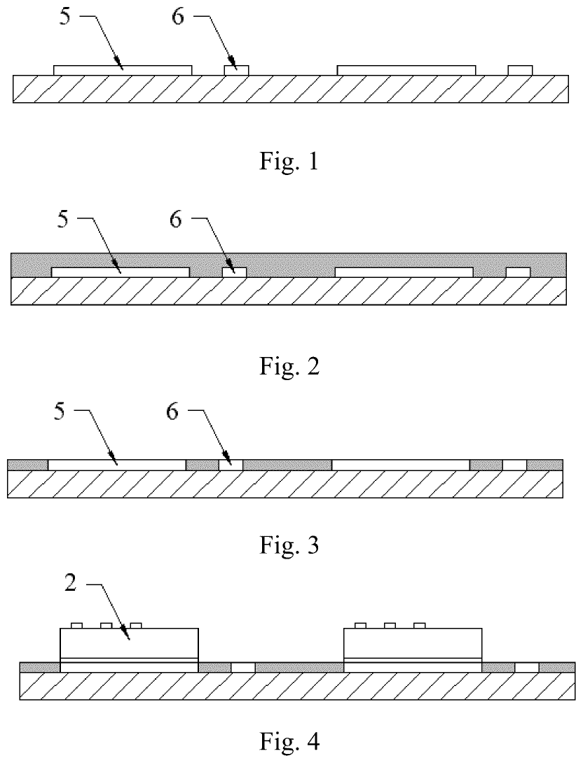

Among them, as shown in FIGS. 1-6, in the chip 2 packaging step, a substrate is provided, and first, a solder pad 5 and a pin 6 are electroplated on the substrate (as shown in FIG. 1). The spatial arrangement is reasonably carried out according to the surface size of the substrate to set the number of groups of the electroplated solder pad 5 and pin 6. Each group is provided with one solder pad 5 and one pin 6. After the electroplating is completed, the solder pad 5 and the pin 6 are encapsulated on the substrate using an encapsulation material (as shown in FIG. 2), and the encapsulation surface is horizontally ground by a mechanical grinding method until the top surfaces of the solder pad 5 and the pin 6 are exposed (as shown in FIG. 3); then the back surface of the chip 2 is facing the solder pad 5 and adhered to the solder pad 5 through an adhesive (as shown in FIG. 4). The functional surfaces of the front and back surfaces of the chip 2 are designed according to actual conditions. For the chip 2 involved in the present disclosure, the back surface of the chip 2 has no output end, and can also be called the non-functional surface of the chip 2. After the mounting is completed, the front surface (functional surface) of the chip 2 faces upward, and one chip 2 is mounted on each solder pad 5; the chip 2 transfers heat to the solder pad 5 through the thermally conductive and insulating adhesive on the back surface and then dissipates it to the outside of the package 1, with high heat dissipation efficiency. If the chip 2 also has an output end on the back surface, the adhesive is a thermally conductive and electrically conductive adhesive, which not only transfers heat but also realizes electrical connection; after the chip 2 is mounted, the chip 2 is completely encapsulated on the encapsulation surface of the solder pad 5 and the pin 6 by continuing to use the encapsulation material (as shown in FIG. 5), and the top of the encapsulation surface is continuously mechanically ground horizontally until the front output end of the chip 2 is exposed, and at this time, the pin 6 is also completely encapsulated (as shown in FIG. 6).

In the present disclosure, the chip 2 is a unidirectional transient voltage suppressor (TVS) chip 2, which is an electronic circuit protection device used to protect electronic equipment from voltage transients and surges. Its internal diode has reverse characteristics. In an electronic circuit, the anode of the diode is connected to the low potential end, and the cathode is connected to the high potential end. The high potential and low potential in electricity refer to high potential charge and low potential charge. The position far from the positive charge has low potential, which is the low potential, and the position close to the positive charge has high potential, which is the high potential. Therefore, the potential gradually decreases along the direction of the electric field line. At this time, almost no current flows through the diode, and the diode is in a cut-off state. This connection method is called reverse bias. When the reverse voltage across the diode increases to a certain value, the reverse current will increase sharply, the diode loses the unidirectional conductivity, and reverse conduction occurs.

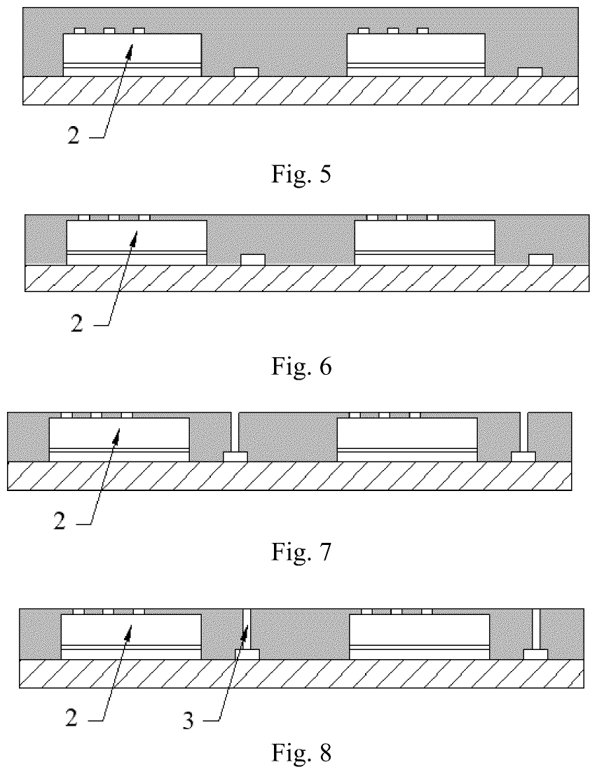

Among them, as shown in FIGS. 7-8, in the drilling and electroplating step, in the chip 2 packaging step, after the chip 2 is mounted, encapsulated and ground to expose the horizontal and flat encapsulation surface of the front output end of the chip 2, a hole is vertically drilled on the encapsulation surface at the corresponding position to remove part of the encapsulation material above the pin 6, so that the top surface of the pin 6 is exposed at the bottom of the drilled hole (as shown in FIG. 7). In the present disclosure, the drilling adopts a laser drilling method, but it is not limited thereto; and a metal post 3 is electroplated in the drilled hole. The pin 6 and the post 3 are made of the same material, so the post 3 and the pin 6 are integrated after electroplating, and the post 3 is electroplated to fill the drilled hole (as shown in FIG. 8).

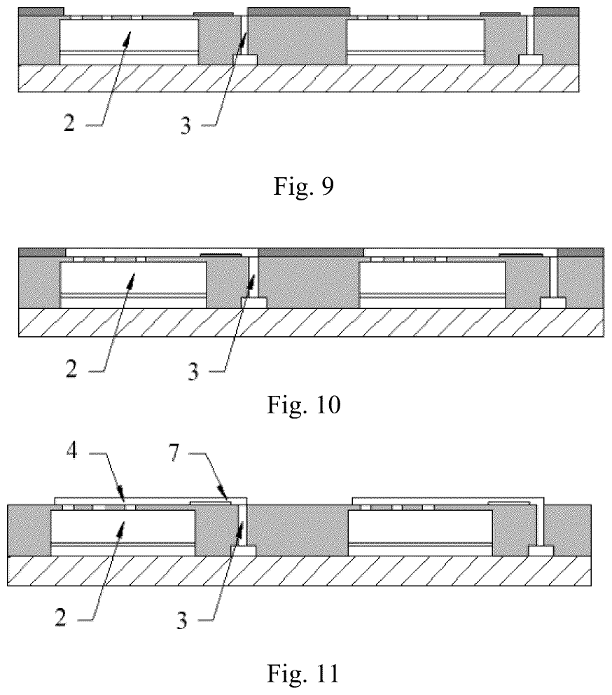

Among them, as shown in FIGS. 9-13, it is a schematic diagram of a first embodiment of the routing layer 4 electroplating step. In the routing layer 4 electroplating step of this embodiment, before electroplating the routing layer 4, a film block is mounted on the corresponding position of the top of the encapsulation surface exposing the front output end of the chip 2 (as shown in FIG. 9). In the present disclosure, the corresponding position here refers to the position close to the post 3. Then the routing layer 4 is electroplated and passes through the film block, and the routing layer 4 covers but does not wrap the film block (as shown in FIG. 10). The two ends of the electroplated routing layer 4 are respectively connected with the front output end of the chip 2 and the post 3 as a whole. The routing layer 4 extends horizontally along the top of the encapsulation surface exposing the front output end of the chip 2. The front output end of the chip 2 is electrically transmitted to the pin 6 through the routing layer 4 and the post 3. The film block is a photoresist film. When electroplating the routing layer 4, it is also necessary to mount a photoresist film on the encapsulation top surface that is not to be electroplated for protection. After the electroplating is completed, all the photoresist films need to be stripped (as shown in FIG. 11). Since the film block is also a photoresist film, it can be removed together in the subsequent electroplating process, saving the process flow. After removing the film block, the narrow segment 7 of the routing layer 4 is formed at the position where the film block is mounted. After the routing layer 4 is electroplated, the encapsulation is continued using the encapsulation material, so that the routing layer 4 is completely encapsulated, and the encapsulation material also fills the gap part below the narrow segment 7 of the routing layer 4 after the film block is removed (as shown in FIG. 12). The narrow segment 7 is thinned due to reduced electroplating below part of the routing layer 4. Up to this point, the encapsulation process is completely completed. Since the same encapsulation material is used, the encapsulation material becomes a complete encapsulation whole after multiple encapsulations. After the encapsulation is completed, the encapsulation material is cut at the dicing street position to separate into product units, and the substrate is stripped. The bottom surfaces of the solder pad 5 and the pin 6 are flush with the package 1 and exposed (as shown in FIG. 13).

In this embodiment, before electroplating the routing layer 4, a photoresist film is mounted on the encapsulation top surface that is not to be electroplated for protection, which is a common method in the electroplating process in this field. At the same time, a small photoresist film block is also mounted at the position close to the post 3 through which the routing layer 4 is electroplated. The film block is smaller than the photoresist film at the normal other protection positions. After electroplating, the photoresist film is removed to form the routing layer 4 and the narrow segment 7 of the routing layer 4. Embedding a small film block in the electroplating route during the electroplating process does not additionally increase or change the process flow, and the process is simple and efficient.

The narrow segment 7 of the routing layer 4 is thinned due to reduced electroplating below part of the routing layer 4, that is, the top surface of the narrow segment 7 is flat and the bottom surface is concave. The size of the mounted film block is controllable, so that the size of the narrow segment 7 is controlled more accurately. When an abnormal overvoltage occurs in the circuit, the package 1 can respond faster and eliminate the danger in time.

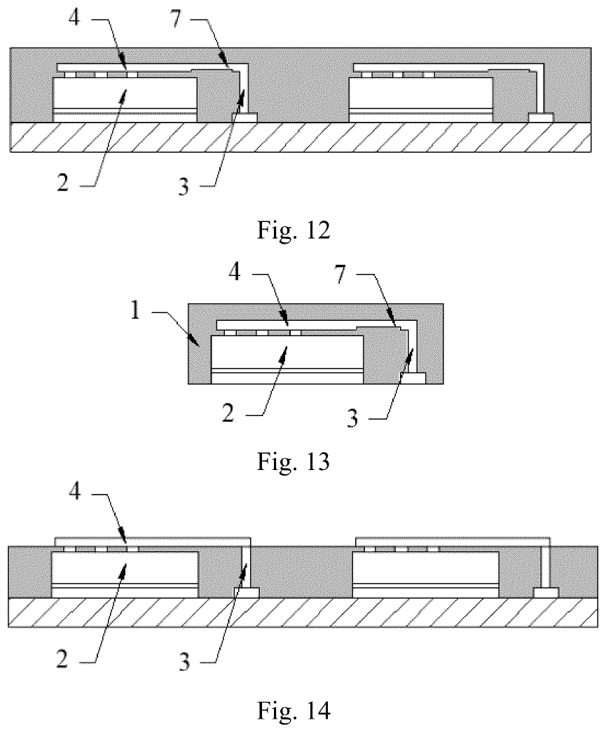

Among them, as shown in FIGS. 14-17, it is a schematic diagram of a second embodiment of the routing layer 4 electroplating step. In the routing layer 4 electroplating step of this embodiment, after the routing layer 4 is electroplated (as shown in FIG. 14), the part of the routing layer 4 close to the post 3 is thinned by etching to form the narrow segment 7 of the routing layer 4, and the narrow segment 7 is thinned by etching above part of the routing layer 4 (as shown in FIG. 15). Then the encapsulation is continued using the encapsulation material, so that the routing layer 4 is completely encapsulated (as shown in FIG. 16). Up to this point, the encapsulation process is completely completed. Since the same encapsulation material is used, the encapsulation material becomes a complete encapsulation whole after multiple encapsulations. After the encapsulation is completed, the encapsulation material is cut at the dicing street position to separate into product units, and the substrate is stripped. The bottom surfaces of the solder pad 5 and the pin 6 are flush with the package 1 and exposed (as shown in FIG. 17).

In this embodiment, the narrow segment 7 is formed by etching the part of the routing layer 4 close to the post 3 after the routing layer 4 is electroplated. The encapsulation material fills the etched part, avoiding the situation that the encapsulation material is insufficiently filled, resulting in cavities and detachment, and the structure is more stable and effective;

The narrow segment 7 of the routing layer 4 is thinned by etching above part of the routing layer 4, that is, the bottom surface of the narrow segment 7 is flat and the top surface is concave. The etching situation is adjusted by controlling parameters such as etching immersion time, etching flow rate, and concentration, which is convenient for observing the etching progress and realizing accurate control of the etching size of the narrow segment 7.

Among them, in the product unitization step, after the routing layer 4 is completely encapsulated, the encapsulation process is completely completed. The number of groups of the solder pad 5 and the pin 6 is set according to the size of the substrate, that is, the number of product units processed by one-time encapsulation in the process is set. The present disclosure takes encapsulating two groups as an example. In the present disclosure, each product unit comprises one chip 2, one solder pad 5, one pin 6, one post 3, one routing layer 4, and one narrow segment 7. Therefore, after the process is completed, it is also necessary to cut the encapsulation material through a cutting process to divide into product units. Each product unit is a package 1. The dicing street is reserved when the substrate is set, and only the encapsulation material exists in the dicing street to ensure the integrity of the product unit after cutting. After cutting into product units, the substrate is removed by mechanical stripping. The solder pad 5 and the pin 6 are flush with the bottom surface of the package 1 and exposed. The chip 2, the routing layer 4, the post 3, and the narrow segment 7 are all encapsulated in the package 1. The package 1 is a high-power TVS packaging device.

The package 1 of the unidirectional TVS in the present disclosure is connected in parallel with the protected device, and the diode is connected in reverse bias. When the circuit works normally, the TVS is in a cut-off state and does not affect the circuit operation. At this time, the voltage on the cathode of the TVS does not exceed its reverse stand-off voltage (VRWM), which is slightly higher than a normal working voltage of the circuit, and VRWM≥1.1× working voltage; when an abnormal overvoltage occurs in the circuit and reaches the breakdown voltage of the TVS (the breakdown voltage refers to the maximum rated voltage that the TVS can withstand: Breakdown Voltage (VBR)), which is usually 10%-15% higher than VRWM, the TVS changes from a high-resistance state to a low-resistance state, and discharges the transient overcurrent caused by the abnormal overvoltage to the ground; at the same time, the abnormal overvoltage is clamped at a lower level (set threshold), that is, the clamping voltage (Vc), which needs to be lower than the maximum withstand voltage of the protected device, thereby protecting the subsequent circuit from damage by the abnormal overvoltage; if an abnormal overvoltage occurs in the circuit, the current passing through the TVS is too large, exceeding the surge it can withstand, or a very large DC source is mistakenly added to both ends of the TVS, causing the TVS to continuously accumulate current and heat, leading to burnout and short circuit. Although the back-end circuit is protected, the TVS tube will release high energy, which has an impact on the protected electronic equipment and devices in the back-end circuit, and even causes a fire. The protected electronic equipment and devices are such as sensor ICs sensitive to temperature. The package 1 of the present disclosure is a high-power TVS with a peak pulse power ≥3000 W. By partially thinning the routing layer 4 encapsulated in the package 1 into a narrow segment 7, the package 1 is connected in parallel with the protected electronic equipment and devices. When the abnormal overvoltage in the circuit directly breaks down and fails the package 1, the narrow segment 7 of the internal routing layer 4 of the package 1 breaks, forming an open circuit, which can avoid the package 1 becoming a low-resistance state, the transient overcurrent being discharged, and the package 1 accumulating high heat, leading to greater dangers such as burnout and fire.

Voltage relationship between TVS and protected devices:
1. The normal working voltage of the protected device should be less than or equal to the reverse stand-off voltage of the TVS, so that the TVS will not conduct during normal operation and will not affect the circuit;
2. The clamping voltage of the TVS must be less than the maximum withstand voltage of the protected device, so that during a transient event, the TVS limits the voltage to the clamping voltage, and the clamping voltage must be low enough to protect the device;
3. The breakdown voltage of the TVS should be higher than the reverse stand-off voltage of the TVS, so that the TVS will not conduct under the normal working voltage. Usually, the breakdown voltage of the TVS is the voltage defined under a specific test current;
4. Voltage hierarchy: normal working voltage of the protected device≤reverse stand-off voltage of the TVS≤breakdown voltage of the TVS≤clamping voltage of the TVS ≤maximum withstand voltage of the protected device.

Taking the protected device as an on-board power supply function module as an example, the package 1 is connected in parallel with the protected device. The working voltage of the protected device is 24V. Assuming that the maximum voltage that the protected device can withstand is 60V, the reverse stand-off voltage of the TVS is greater than or equal to 26.4V, then the clamping voltage of the TVS needs to be less than or equal to 50V, and the breakdown voltage of the TVS is approximately equal to a range of 29.04V-30.36V; when an abnormal overvoltage occurs in the circuit, but the abnormal overvoltage is within the breakdown voltage range of the TVS, the TVS works normally to discharge the current. However, when the abnormal overvoltage of the circuit exceeds the breakdown voltage of the TVS, the current passing through the TVS is too large, exceeding the surge it can withstand. The heat accumulated by the TVS, that is, the heat accumulated on the internal routing layer of the package 1, causes the narrow segment 7 to fuse, forming an open circuit, avoiding the TVS being burned and causing a fire, etc. However, the open circuit cannot protect the protected device, which may expose the protected device to the risk of overvoltage. In an actual circuit, a TVS warning device can be connected. When the TVS is open-circuited, the warning device has an abnormality, so that the TVS can be replaced in time to prevent damage to the protected device. The present disclosure is not limited thereto.

Both the electroplated routing layer 4 and its narrow segment 7 are made of metal materials, such as copper. According to the specific type and functional requirements of the protected device, the TVS performance selection of the package 1 is set, and the maximum breakdown voltage of the package 1 is known as U. At a temperature of 25° C., L is the line length of the narrow segment 7, W is the line width of the narrow segment 7, and A is the cross-sectional area of the narrow segment 7.

The relationship between the fusing of the narrow segment 7 of the electroplated routing layer 4 and the current can be calculated through the following formulas and steps:
1. Fusing current calculation (adiabatic model): Within the pulse current duration tₚᵤₗₛₑ, the relationship between the fusing current I_{fuse} and the cross-sectional area A is:

$${I}_{fuse} = A \times \sqrt{\frac{{ρ}_{m} ( c Δ T + L )}{ρ \cdot {t}_{pulse}}} . \qquad Formula 1$$

Wherein parameter description:
ρm: Density of copper (8960 kg/m³);
c: Specific heat capacity of copper (385 J/(kg·K));
ΔT: Temperature difference between melting point and ambient temperature (1060 K, corresponding to 1085° C. melting point);
L: Latent heat of fusion of copper (209,000 J/kg);
ρ: Resistivity of copper (1.68×10⁻⁸Ω·m);
tₚᵤₗₛₑ: Pulse time (seconds).
2. Resistance and voltage drop: The resistance R and voltage V_{drop} of the conductor are:

$$R = ρ L / A , {V}_{drop} = IR = I ρ L / A . \qquad Formula 2$$

Given that the breakdown voltage U=V_{drop}, assuming that the pulse time tₚᵤₗₛₑ is subject to testing, and substituting into Formula 1 and Formula 2, the line length L can be obtained, the fusing current I_{fuse} can be obtained, and then the cross-sectional area A of the narrow segment 7 can be obtained according to the current-voltage relationship. The size of the narrow segment is set according to the cross-sectional area, and the cross-sectional area A=wt, where w is the width and t is the thickness. By setting the width, thickness and length of the narrow segment 7, the narrow segment 7 reaches the maximum cross-sectional area. When an abnormal overvoltage greater than the breakdown voltage range of the package 1 occurs in the circuit, heat accumulates at the narrow segment 7 and is fused, preventing burnout and even fire.

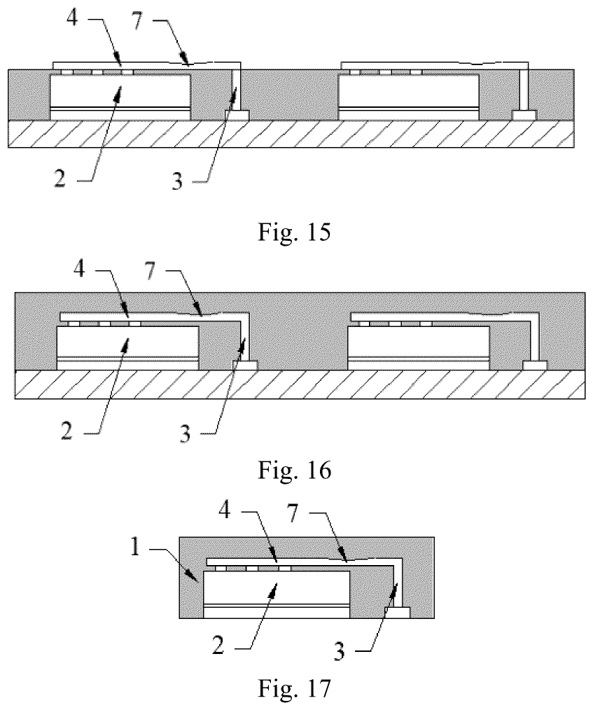

A high-power TVS packaging structure can be obtained through the above high-power TVS packaging method. As shown in FIG. 18, it is a cross-sectional view of the first embodiment of the packaging structure. The package 1 encapsulates:
A solder pad 5 and a pin 6, the solder pad 5 being arranged on one side of the pin 6;
A chip 2, the back surface of the chip 2 being mounted towards the solder pad 5, and the front surface of the chip 2 being provided with an output end;
A post 3 vertically electroplated on the pin 6;
A routing layer 4, the routing layer 4 electrically connecting the front output end of the chip 2 with the post 3, the routing layer 4, the front output end of the chip 2, and the post 3 being electroplated as a whole, the routing layer 4 comprising a narrow segment 7, and when the input power of the circuit is greater than the rated power of the chip, the narrow segment 7 breaks.

The solder pad 5 and the pin 6 are formed by simultaneous electroplating on a substrate. After encapsulation, the top surfaces of the solder pad 5 and the pin 6 are exposed by grinding. The back surface of the chip 2 is mounted on the solder pad 5 and encapsulated again, the front output end of the chip 2 is exposed by grinding, and a hole is drilled on the encapsulation surface until the top surface of the pin 6 is exposed. The post 3 is formed by electroplating in the hole. The routing layer 4 extends horizontally along the top of the encapsulation surface exposing the front output end of the chip 2. The front output end of the chip 2 is electrically transmitted to the pin 6 through the routing layer 4 and the post 3. The routing layer 4 is continuously encapsulated, and the overall encapsulation constitutes the package 1. Before electroplating the routing layer 4, a film block is mounted on the corresponding position of the top of the encapsulation surface exposing the front output end of the chip 2, then the routing layer 4 is electroplated and passes through the film block, and the narrow segment 7 of the routing layer 4 is formed at the position where the film block is mounted. The film block is a photoresist film. After the routing layer 4 is electroplated, the film block is stripped and the routing layer 4 is encapsulated. The encapsulation material fills the gap after the film block is removed. After the package 1 is stripped from the substrate, the solder pad 5 and the pin 6 are flush with the bottom surface of the package 1 and exposed.

In this embodiment, before electroplating the routing layer 4, a photoresist film is mounted on the encapsulation top surface that is not to be electroplated for protection. At the same time, a small photoresist film block is also mounted at the position close to the post 3 through which the routing layer 4 is electroplated. The film block is smaller than the photoresist film at the normal other protection positions. After electroplating, the photoresist film is removed to form the routing layer 4 and the narrow segment 7 of the routing layer 4. No additional process flow is added or changed, and the process is simple and efficient.

The narrow segment 7 of the routing layer 4 is thinned due to reduced electroplating below part of the routing layer 4, that is, the top surface of the narrow segment 7 is flat and the bottom surface is concave. The size of the mounted film block is controllable, so that the size of the narrow segment 7 is controlled more accurately. When an abnormal overvoltage occurs in the circuit, the package 1 can respond faster and eliminate the danger in time.

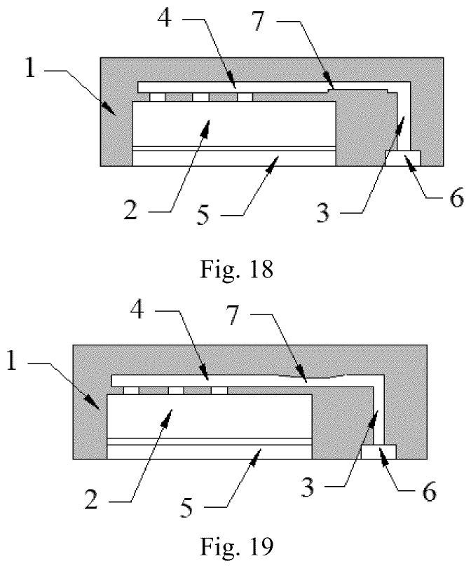

As shown in FIG. 19, it is a cross-sectional view of the second embodiment of the packaging structure. The difference between the second embodiment and the first embodiment is that the part of the routing layer 4 close to the post 3 is thinned by etching to form the narrow segment 7 of the routing layer 4.

The narrow segment 7 is formed by etching the part of the routing layer 4 close to the post 3 after the routing layer 4 is electroplated. The encapsulation material fills the etched part, avoiding the situation that the encapsulation material is insufficiently filled, resulting in cavities and detachment, and the structure is more stable and effective.

The narrow segment 7 of the routing layer 4 is thinned by etching above part of the routing layer 4, that is, the bottom surface of the narrow segment 7 is flat and the top surface is concave. The etching situation is adjusted by controlling parameters such as etching immersion time, etching flow rate, and concentration, which is convenient for observing the etching progress and realizing accurate control of the etching size of the narrow segment 7.

In all encapsulation steps of the present disclosure, the encapsulation material used is a molding compound, and the specific material can be epoxy resin, cyanate ester, polyimide, etc., which has low cost and good curing performance. The packaging process plays an important role in the field of semiconductor manufacturing, mainly reflected in protection, connection, support, reliability and promoting technological progress; the encapsulation method is a common molding injection molding method in this field.

All post-encapsulation grinding processes of the present disclosure use grinding machines commonly used in this technical field to perform surface treatment on the encapsulation surface, that is, horizontal mechanical grinding on the top of the encapsulation surface. Finally, the ground surface is horizontal and flat after grinding, and the outer surface of the entire packaging structure is flat and smooth.

In all steps using the electroplating process of the present disclosure, first, a photoresist film is used to form electroplating protection on the surface through photolithography technology such as exposure and development. The areas not to be electroplated are protected with the photoresist film, and the areas to be electroplated are exposed. Then, a metal seed layer is formed in the area to be electroplated through an appropriate method such as sputtering or copper deposition. The metal seed layer is made of copper or other metal materials. The metal seed layer is to ensure the bonding force between the subsequently electroplated metal and the metal, and between the metal and the encapsulation material, and at the same time provide a surface for the attachment of conductive ions for electroplating, ensuring the electroplating effect. The entire steps and materials used in the electroplating process are also common knowledge in this field. The metals electroplated in all electroplating processes of the present disclosure are all metal copper materials.

The present disclosure: By locally thinning the electroplated routing layer 4 into a narrow segment 7 of a certain size, when the package 1 is connected in parallel to the circuit of the protected device, if an abnormal overvoltage exceeding the breakdown voltage of the package 1 occurs in the circuit, heat accumulates at the narrow segment 7 of the package 1 and is fused into an open circuit, avoiding the situation where the package 1 is burned and causing a fire. Moreover, the narrow segment 7 is reduced in size through electroplating or etching after electroplating, and the process is simple, efficient and reliable.

It can be understood that the present disclosure is described through some embodiments. Those skilled in the art know that various changes or equivalent substitutions can be made to these features and embodiments without departing from the spirit and scope of the present disclosure. In addition, modifications can be made to these features and embodiments under the teaching of the present disclosure to adapt to specific situations and materials without departing from the spirit and scope of the present disclosure. Therefore, the present disclosure is not limited to the specific embodiments disclosed herein, and all embodiments falling within the scope of the claims of the present disclosure belong to the scope protected by the present disclosure.

What is claimed is:

1. A high-power TVS packaging method, comprising steps of:
chip packaging: mounting a chip on a substrate with an electroplated pin, encapsulating the chip and grinding a top of an encapsulation surface until a front output end of the chip is exposed;
drilling and electroplating: drilling vertically through the top of the encapsulation surface until the pin is exposed, and electroplating a post within a drilled hole;
routing layer electroplating: electroplating a routing layer on the top of the encapsulation surface, the routing layer electrically connecting the front output end of the chip with the post, the routing layer, the front output end of the chip, and the post being electroplated as a whole, the routing layer comprising a narrow segment; continue encapsulating to completely encapsulate the routing layer, wherein if an input power of a circuit is greater than a rated power of the chip, the narrow segment breaks;
product unitization: stripping the substrate to obtain a package product unit.

2. The high-power TVS packaging method according to claim 1, wherein in the step of chip packaging, the substrate is provided, the substrate being electroplated with a solder pad and the pin; after encapsulation and grinding, top surfaces of the solder pad and pin are exposed; a back surface of the chip is mounted on the solder pad and encapsulated, so that the chip, the solder pad, and the pin are all completely encapsulated.

3. The high-power TVS packaging method according to claim 1, wherein in the step of routing layer electroplating, a film block is mounted on a corresponding position of the top of the encapsulation surface exposing the front output end of the chip before the routing layer is electroplated, then the routing layer is electroplated; through the film block, the narrow segment of the routing layer is formed at a position where the film block is mounted.

4. The high-power TVS packaging method according to claim 3, wherein in the step of routing layer electroplating, the film block is a photoresist film.

5. The high-power TVS packaging method according to claim 1, wherein in the step of routing layer electroplating, a part of the routing layer closing to the post is thinned by etching to form the narrow segment of the routing layer.

6. The high-power TVS packaging method according to claim 3, wherein in the step of routing layer electroplating, the routing layer extends horizontally along the top of the encapsulation surface exposing the front output end of the chip, and the front end of the chip is electrically connected to the pin through the routing layer and the post.

7. The high-power TVS packaging method according to claim 5, wherein in the step of routing layer electroplating, the routing layer extends horizontally along the top of the encapsulation surface exposing the front output end of the chip, and the front end of the chip is electrically connected to the pin through the routing layer and the post.

8. The high-power TVS packaging method according to claim 2, wherein in the step of product unitization, after stripping the substrate, the solder pad and the pin are flush with a bottom surface of the package and exposed.

9. A high-power TVS packaging structure, comprising a package, wherein the package encapsulates:
a solder pad and a pin, the solder pad being set on one side of the pin;
a chip, a back surface of the chip being mounted towards the solder pad, and a front surface of the chip having an output end;
a post vertically electroplated on the pin; and
a routing layer, the routing layer electrically connecting the front output end of the chip with the post, the routing layer, the front output end of the chip, and the post being electroplated as a whole, the routing layer comprising a narrow segment, wherein if an input power of a circuit is greater than a rated power of the chip, the narrow segment breaks.

10. The high-power TVS packaging structure according to claim 9, wherein the solder pad and the pin are formed by electroplating on a substrate at the same time; after encapsulation and grinding, top surfaces of the solder pad and the pin are exposed; the back surface of the chip is mounted on the solder pad and encapsulated; the front output end of the chip is exposed by grinding, and the top surface of the pin is exposed by drilling on an encapsulation surface; the post is formed by electroplating within a hole.

11. The high-power TVS packaging structure according to claim 10, wherein the routing layer extends horizontally along a top of the encapsulation surface exposing the front output end of the chip, the front end of the chip is electrical connected to the pin through the routing layer and the post, the routing layer is encapsulated, and an overall encapsulation forms the package.

12. The high-power TVS packaging structure according to claim 11, wherein a film block is mounted on a corresponding position of the top of the encapsulation surface exposing the front output end of the chip before the routing layer is electroplated, then the routing layer is electroplated; through the film block, the narrow segment of the routing layer is formed at a position where the film block is mounted.

13. The high-power TVS packaging structure according to claim 12, wherein, the film block is a photoresist film.

14. The high-power TVS packaging structure according to claim 9, wherein, a part of the routing layer closing to the post is thinned by etching to form the narrow segment of the routing layer.

15. The high-power TVS packaging structure according to claim 10, wherein, after stripping the package from the substrate, the solder pad and the pin are flush with a bottom surface of the package and exposed.
